(19) United States
(12) Patent Application Publication
(10) Pub. No.: US 2026/0096245 A1
(43) Pub. Date: Apr. 2, 2026

(54) METHODS, SYSTEMS, AND APPARATUSES FOR PRODUCING, GENERATING AND UTILIZING POWER AND ENERGY

(71) Applicants: Yttrium Kai Saiyan, Tyler, TX (US); Amethyst Kai Saiyan, Tyler, TX (US)

(72) Inventors: Yttrium Kai Saiyan, Tyler, TX (US); Amethyst Kai Saiyan, Tyler, TX (US)

(21) Appl. No.: 19/274,215

(22) Filed: Jul. 18, 2025

Related U.S. Application Data
(63) Continuation of application No. 19/210,240, filed on May 16, 2025.
Application No. 19/210,240 is a continuation of application No. 18/172,554, filed on Feb. 22, 2023, now Pat. No. 12,310,143.
Application No. 18/172,554 is a continuation-in-part of application No. 17/699,586, filed on Mar. 21, 2022, now abandoned.
(60) Provisional application No. 63/164,100, filed on Mar. 22, 2021.

(51) Int. Cl. H10F 77/42; H02S 40/22; H10F 19/80; H10F 77/30; H10F 77/45; H10F 77/50

(52) U.S. Cl. CPC H10F 77/488; H02S 40/22; H10F 19/804; H10F 77/315; H10F 77/45; H10F 77/50

(57) ABSTRACT

The present disclosure relates to a device for converting photonic energy to electrical energy. The device comprises one or more photonic collectors configured to collect photonic energy; one or more mirrors configured to concentrate the collected photonic energy; one or more gain mediums configured to receive, on one or more absorption faces, the concentrated photonic energy; and a photoelectric material configured to receive the photonic energy from the one or more gain mediums and convert the photonic energy into electrical energy, wherein the one or more gain mediums comprise a crystalline lattice structure selected from the group consisting of: Ti³⁺:Al₂O₃, Nd:YAG, Yb³⁺:YAG, and Ce:YAG.

### PRIORITY

This application claims the benefit under 35 U.S.C. § 120 as a continuation of application Ser. No. 19/210,240, filed May 16, 2025, which claims the benefit under 35 U.S.C. § 120 as a continuation of application Ser. No. 18/172,554, filed Feb. 22, 2023, which claims the benefit under 35 U.S.C. § 120 as a continuation-in-part of application Ser. No. 17/699,586, filed Mar. 21, 2022, which claims the benefit under 35 U.S.C. § 119 (c) of provisional application No. 63/164,100, filed Mar. 22, 2021, the entire contents of which are hereby incorporated by reference as if fully set forth herein.

Aspects of the invention are disclosed in the following description and related drawings directed to specific embodiments of the invention. Those skilled in the art will recognize that alternate embodiments may be devised without departing from the spirit or the scope of the claims. Additionally, well-known elements of exemplary embodiments of the invention will not be described in detail or will be omitted so as not to obscure the relevant details of the invention. Further, to facilitate an understanding of the description discussion of several terms used herein follows.

As used herein, the word “exemplary” means “serving as an example, instance or illustration.” The embodiments described herein are not limiting, but rather are exemplary only. It should be understood that the described embodiment are not necessarily to be construed as preferred or advantageous over other embodiments. Moreover, the terms “embodiments of the invention”, “embodiments” or “invention” do not require that all embodiments of the invention include the discussed feature, advantage or mode of operation.

In an exemplary embodiment, an Empyreal Reaper may be provided.

This solid-state exemplary embodiment may include a variety of different materials that allow for the conversion of photonic energy into electrical energy. These materials may include a composition of coatings, a gain medium, a resin, and a photoelectric material. The exemplary embodiment may be configured in such a way that allows for the harnessing of ambient photonic energy, and its conversion it into clean, useable electrical energy. This solid-state exemplary embodiment may be composed of a variety of different materials that allow for the conversion of photonic energy into electrical energy. These materials may include a composition of coatings, a gain medium, a resin, and a photoelectric material. The exemplary embodiment may be configured in such a way that allows for the harnessing of ambient photonic energy, and its conversion it into clean, useable electrical energy.

### Structure

This exemplary embodiment has a structure that may contain the following various materials. A possible design and order for these materials are as follows. The solid-state exemplary embodiment may contain only one, a combination, or all the following materials.

This exemplary embodiment may be enclosed in a hermetic packaging that may allow for protection against environmental changes.

The order of which these materials are assembled may be the order as follows or may be any other order that allows for the most effective conversion of photonic energy into electrical energy. The orientation of these materials may be layered and may include different types of glass, an atomic mirror, multiple gain mediums, photoelectric materials, coatings and/or resins.

Glass casing: This exemplary embodiment may be encapsulated behind a protective glass shielding that allows for light to readily transmit through the material, while protecting the structure from environmental changes such as temperature, as well as climate alterations.

Ridged Mirror: An atomic mirror that captures light at a variety of indices and culminates this light into a coherent beam. This allows for the system to capture sunlight at varying incident angles and focus this light into one beam with the same incident angle most readily absorbed by the medium behind the mirror.

This structure allows for the exemplary embodiment to absorb a larger portion of ambient sunlight and may decrease the amount of reflection losses upon entry as the light is columnated into one coherent beam that is more readily absorbed by the exemplary embodiment.

Dichroic mirror: A chemical composition of various materials that may be semipermeable to specific wavelengths of light. For instance, this may include wavelengths intrinsic to the gain medium's peak absorption bandgap.

These various materials may be composed of alternating layers of optical coatings that have varied refractive indices. The variation in indices may allow to produce phased reflections that are tuned to allow specific wavelengths of light to permeate the material, while reflecting all other wavelengths.

Those wavelengths allowed to permeate the material, may allow for the potential for stimulated emission (Saiyan Emanation) of newly generated photonic energy within the gain medium. These wavelengths may be intrinsic to the peak absorption bandgap of the gain medium. As the gain medium readily absorbs these wavelengths, the electrons within the crystalline lattice structure may become energized and displaced from their current energy level. The displacement of electrons and their movement from a charged to discharged position, is what may allow for the generation of new energy.

This material may also be tuned to reflect wavelengths of light that are within the gain medium's peak emission bandgap. The newly generated energy from the potential Saiyan Emanation within the gain medium may exit the material in the form of light. The wavelength of this light may be within the gain medium's emission bandgap; and may be absorbed by the photoelectric material within the solid-state device.

This coating may also act as a layer of protection for the solid-state device. The chemical or molecular composition of the coating will reflect wavelengths of light that cause degradation within the exemplary materials of the solid-state device. Heat and infrared/ultraviolet spectrum light may be reflected to achieve this substantial decrease in degradation.

Cold Mirror Coating: A chemical composition of various materials tuned to reflect a high percentage of light within the UV spectrum, or any other spectrums of light that are unwanted within the solid-state exemplary embodiment at a specific incident angle (for example at a 45-degree incident angle). It may also be tuned to transmit a high percentage of light within the visual spectrum, or any other spectrum of light that is wanted within the solid-state exemplary embodiment at a specific incident angle (for example at a 45-degree incident angle).

It may also simultaneously reflect the same light it may transmit when these wavelengths permeate the mirror at an opposing incident angle (for example at a 0-degree incident angle). This is important for the spectrum of light that is within the peak absorption spectrum of the gain medium. When light in this absorption spectrum enters the coating at a specific incident angle, (for example at a 45-degree incident angle), the light may permeate the coating and enter the solid-state exemplary embodiment. The light that is within the absorption spectrum but is not absorbed by the gain medium that would normally be reflected out of the system, may instead by reflected by the design of the cold mirror. This is because this light may exit the material at a specific incident angle (for example at a 0-degree incident angle). The mirror may be tuned to these specific incident angles in order to capture wavelengths of light within the peak absorption spectrum of the gain medium and trap it within the system.

This mirror may allow for the creation of a virtual resonating cavity within the solid-state exemplary embodiment. This is important for the gain medium as this is the sight at which Saiyan Emanation may take place. The more light that is available for the gain medium to absorb reach saturation potential, the more photonic interactions may take place.

Anti-reflective coating: A chemical composition of various materials that may tuned to allow for wavelengths of light within the peak absorption bandgap of the gain medium to seamlessly pass through the material with minimal reflection losses. The allowing for a higher percentage of light within this specific spectrum may create the potential for stimulated emission (Saiyan Emanation) of newly generated photonic energy.

This may be composed of a variety of different materials. The chemical or molecular compound may effectively transmit the specific wavelengths of light that are within the peak absorption bandgap of the gain medium. This coating may also decrease the amount of photonic energy that is lost, while increasing the amount of available photonic energy to initiate the stimulated emission within the gain medium. This may be completed by the AR coating's ability to effectively produce two reflections that interfere destructively with one another allowing for a higher percentage of light within a specific bandgap to permeate the material with minimal reflection losses.

Once the materials within the solid-state device reach saturation, this coating may allow for the excess light to escape. This may decrease the potential for the material to become oversaturated.

Gain medium: A crystalline lattice structure whose peak emission bandgap may match the peak absorption bandgap of the chemicals that make up the material with high photoexcitation characteristics. This crystalline lattice structure may also have a gain potential associated with its peak absorption bandgap. This gain potential is what may allow for the stimulated creation and emission of new photons. These new photons may then exit the material in the form of the gain medium's peak emission bandgap.

The gain medium may be comprised of various chemical compounds that bind together in a mono or polycrystalline lattice structure. These may include synthetically grown or naturally occurring crystals that have certain optical properties. Some examples include Nd: YAG, Y²⁺: CaF₂, Ti³⁺: Al₂O₃, Nd: KGW, or any crystal, ion-oxide, or metal oxide that has photoexcitation properties.

Resin: a chemical composition of various materials that allow for the adhesion between the layers of materials within the exemplary embodiment. The resin may contain an index of refraction that is intrinsic to the index of refraction of the gain medium, or any other material that the resin is adhering together. The matching of refractive indices allows for the seamless transition of light from the different layers of materials within this solid-state exemplary embodiment.

Encapsulant: a chemical composition of various materials that allow for the adhesion between layers of materials within the exemplary embodiment. The encapsulant may contain an index of refraction that is intrinsic to the index of refraction of the gain medium, or any other material that the resin is adhering together. The matching of refractive indices allows for the seamless transition of light from the different layers of materials within this solid-state exemplary embodiment. The encapsulant may also function as a protective layer, decreasing the risk for delamination, corrosion, and environmental damage within the solid-state exemplary embodiment.

Antireflective coating: a chemical composition of various materials that contain varying refractive indices that are tuned to minimize reflection losses when specific wavelengths of light permeate a material. The purpose of this chemical composition is to match the refractive indices of the varying materials within the solid-state device. The matching of refractive indices between materials allows for a higher percentage of light to pass from one material to another with minimal losses resulting from reflection.

Photoelectric material: chemical composition of various materials that become excited by photonic energy in the peak emission bandgap associated with the gain medium. This excitation wavelength may stimulate the movement of free electrons from their bonded state. These free electrons travel together in one coherent current. This current is transferred from the photoelectric material into the circuitry components. At this stage, the photonic energy may be converted into usable electrical energy.

Highly Reflective coating: This coating acts as a mirror that may have reflective capabilities for the wavelengths of light that are within the peak absorption bandgap of the gain medium. This reflective coating allows for the materials within the solid-state device to reach their saturation capabilities. This increases the ability for the gain medium to undergo increased instances of stimulated emission.

Junction Box: A junction box may also be incorporated into the circuitry components of the solar panel. The junction box may regulate the electricity flow from each individual panel allowing for effective transition of electrons from the reaper material into the circuitry components. It may also allow for the user to dictate the performance of each individual solar panel. If one panel appears to have an alteration in its electron output, the user may identify which panel is having this issue and address it.

The junction box may digitalize the performance of each solar panel. The user may be able to enable or disable any of the associated panels with the use of software. There may also be opportunities for the system to be run by a computer and have certain parameters for electron flow that is regulated by computation.

This exemplary embodiment may have the ability to sustainably convert photonic energy into usable electrical energy. It may consist of a variety of materials that may have certain photoexcitation properties. For instance, the gain medium may be composed of various chemical compounds that together form a crystalline lattice structure that has photoexcitation properties. This molecular compound may have a specific orientation and lattice structure that allows for the process of spontaneous emission to be controlled and modified into stimulated emission (Saiyan Emanation). When wavelengths of light that match this material's specific peak absorption range interact with the substrate, the photons may have the ability to indirectly interact with the electrons within the gain medium. When this interaction takes place, the electron becomes excited and becomes energized. As the electron moves, it releases energy in the form of photons. These newly generated photons may be synonymous with the newly generated light that is illuminated from the gain medium. This newly generated light is what is converted into usable, electrical energy by the photoelectric material within the solid-state device.

As stated previously, the solid-state device may be comprised of none, one, or several different coatings. These coating may be a dichromatic coating, an antireflective coating, or any other type of coating that allows for photonic energy to seamlessly enter the gain medium. The coating may also simultaneously have reflective properties to specific wavelengths as well.

If a dichroic mirror is used, it may be tuned to transmit light that is within the gain medium's peak absorption bandgap, while reflecting light that is within the gain medium's peak emission bandgap. By allowing for the seamless transmission of selected wavelengths of light, the potential for stimulated emission (Saiyan Emanation) within the gain medium is created. Because the gain medium may have a high absorption efficiency for this specific bandgap of light, electrons throughout the structure may become energized. As the electrons become energized, they may move from their charged position to a discharged energy level. This movement of electrons may consequently release energy in the form of photons. These photons make up the photonic energy that is emitted from the gain medium. This newly emitted energy may then be prevented from exiting the top face of the gain medium because of the dichroic mirror. This photonic energy may then instead become focused on the face of the photoelectric material.

This dichroic coating may also be tuned to reflect light that is within the UV and Infrared Spectrum as well. This decreases the risk for damage to the components of the solid-state device.

Another option may be to use an antireflective coating to allow for the seamless transmission of photonic energy within the peak absorption spectrum of both the gain medium and the photoelectric material. This coating may be comprised of various materials that increase the transmissive ability of photonic energy by decreasing associated losses accompanied by reflection. This may increase the total amount of photonic energy that is able to enter the gain medium, as well as the photoelectric material.

Another option may be a cold mirror to allow for the creation of a virtual resonating cavity. This coating may be tuned to reflect and transmit specific wavelengths of light at a specific incident angle. When light that is within the peak absorption spectrum of the gain medium stimulates the mirror, it may permeate the material at a specific incident angle. Any light that is not absorbed readily by the gain medium, may be reflected at a specific incident angle into the system for a second chance at absorption by the gain medium. This may allow for Saiyan Emanation to take place within the gain medium as it reaches saturation potential.

This solid-state device may also be comprised with a photoelectric material that may or may not have coatings deposited on either face. The purpose of the photoelectric material is to absorb photonic energy either from ambient sunlight, and/or from the light emitted by the stimulated gain medium. The photoelectric material may also require a coating that allows for seamless transmission of photonic energy. This coating may be a dichromatic, antireflective, or any other type of coating design that allows for photonic energy within the peak absorption spectrum of the photoelectric material to freely enter with minimal reflection losses. If using an antireflective coating, this coating may function as an index matching coating that decreases reflection losses when photonic energy exits the gain medium and enters the photoelectric material.

The photoelectric material may also be comprised with a coating on the back face as well. This coating may be a highly reflective coating, a dichroitic coating, or any other type of optical coating material that minimizes the amount of light that is lost through the back face. The trapping of photonic energy within the solid-state exemplary embodiment allows for more photonic energy to become available within the device to either become absorbed into the photoelectric material, or to create stimulated emission (Saiyan Emanation) within the gain medium.

If the back side of the reaper or gain medium were not coated, then the device may use the back face as another absorption face. This back side may absorb photonic energy reflected from the ground or off a mirror that is strategically placed to reflect photonic energy into this back face. This may be known as bifacial pumping, where two or more faces of the reaper are used to capture and absorb photonic energy.

As the photoelectric material absorbs photonic energy that is within its peak absorption spectrum, the photonic energy may then stimulate movement of electrons within the material. These freely flowing electrons then travel down the material in the form of an electric current. This electric current may then be processed through a circuit board in the form of usable energy that may be applied in a variety of use cases.

### How it can be Made:

This exemplary embodiment is composed of a variety of materials that may be composed of a variety of different molecular and chemical compounds. Each molecular and chemical compound is intrinsic to the solid-state device in the sense that these chemical bonds are what allow for the efficient conversion of photonic energy into usable electrical energy.

### Coatings

Dichromatic Coating: This may be composed of a variety of different materials. The chemical or molecular compound is selectively permeable to light that is within the peak emission wavelengths of the sun. This wavelength consequently may also be within the bandgap of the solid-state device's gain medium's peak absorption.

This coating is applied to the polished surface of the gain medium. There are multiple ways to adhere this coating to the exemplary embodiment. One of which includes evaporating the chemical or molecular compound evenly across the surface. This allows for the coating to bond to the material seamlessly which may enhance its overall effectiveness.

There are a variety of processes that may be used to evaporate this compound onto the surface of the substrate. Some of which include, but are not limited to, electron beam sputtering, electron beam physical vapor deposition, ion assisted deposition, ion beam sputtering, or any other type of optical coating process that allows for the effective distribution of dichroitic coatings.

A possible process when using an ion beam sputtering technique is as follows:

Using a vacuum chamber and a target material (a metal oxide or any other type of material that releases electrons), a high energy ion beam is directed at the target. The ions within the beam may transfer their momentum into the target material causing atoms or molecules to sputter off. These high energy atoms/molecules that may sputter off the target material may deposit onto the substrates. Uniform, high density coatings may be achieved due to the presence of low-pressure oxygen within the coating to re-oxidize any free molecule or atom that may have become dissociated during the sputtering process.

The resulting coating may be an extremely smooth, clean surface finish that may also withstand temperature and humidity fluctuations within its environment.

Anti-Reflective Coatings: These coatings are applied to the faces of the gain medium and the photoelectric material. Having both materials coated with this anti-reflective coating may allow for the solid-state device to decrease its overall loss in photonic energy. They allow for the materials to reach the point of saturation and then allows the light to exit to prevent over saturation.

This coating is applied to the polished surface of the gain medium. There are multiple ways to adhere this coating to the exemplary embodiment. One of which includes evaporating the chemical or molecular compound evenly across the surface. This allows for the coating to bond to the material seamlessly which may enhance its overall effectiveness.

There are multiple ways to effectively bond this type of coating upon the surface of the substrate. For instance, electron beam sputtering, electron beam physical vapor deposition, ion assisted deposition, ion beam sputtering, or any other type of coating process that allows for the effective and efficient deposition of antireflective coatings upon the surface of a substrate. When using electron beam sputtering, a possible adhering process is as follows.

To initiate this process, the coating material may be heated within a high vacuum chamber until it becomes vaporized. It may be heated through electron beam bombardment when using dielectrics, or it may be heated resistively when using metals. As the coating material vaporizes, vapor may then stream away and recondense onto the surface of the substrate intended for coating.

Another process that may be utilized when using electron beam sputtering includes electron-beam physical vapor deposition. This may allow for coating at a high deposition rate without needing to heat the substrate at such high temperatures. When initiating this coating process, an electron beam may be generated and accelerated to a high kinetic energy. This high energy beam may then be directed at the evaporation material causing the electrons within the material to decrease unto a lower energy level. Interactions with the evaporation material causes kinetic energy to become converted into alternative forms of energy. Thermal energy may be one of the alternative forms of energy and may conduct heat into the evaporation material causing it to melt. The melt may then vaporize and rise to coat the surface of the substrate.

Highly Reflective Coatings: This may be composed of a variety of different materials. The chemical or molecular compound may act as a mirror within the solid-state device. This coating's reflective properties that may either reflect all wavelengths or may selectively reflect light that is within the gain medium's peak absorption bandgap. This allows for the continuous stimulation emission within the gain medium of the solid-state device. As the initial photonic energy saturates the material and exits, excess photonic energy may then be reflected to initiate stimulated emission within the gain medium.

This coating may be located on the side furthest from the surface dichromatic layer. This allows for the ability for enhanced trapping of the gain medium's primary excitation wavelengths. With this ability to control and reflect this light, the exemplary embodiment's ability to initiate stimulated emission may be substantially improved.

This coating is applied to the polished surface of the gain medium. There are multiple ways to adhere this coating to the exemplary embodiment. Of which may include, but are not limited to, electron beam sputtering, electron beam physical vapor deposition, ion assisted deposition, ion beam sputtering, or any other type of coating process that allows for the effective and efficient deposition of highly reflective coatings upon the surface of a substrate.

A possible process when using an ion beam sputtering technique is as follows:

Using a vacuum chamber and a target material (a metal oxide or any other type of material that releases electrons), a high energy ion beam is directed at the target. The ions within the beam may transfer their momentum into the target material causing atoms or molecules to sputter off. These high energy atoms/molecules that may sputter off the target material may deposit onto the substrates. Uniform, high density coatings may be achieved due to the presence of low-pressure oxygen within the coating to re-oxidize any free molecule or atom that may have become dissociated during the sputtering process.

The resulting coating may be an extremely smooth, clean surface finish that may also withstand temperature and humidity fluctuations within its environment.

### Gain Medium

Crystalline-Lattice structure: This molecular compound may have a specific orientation and lattice structure that allows for the process of spontaneous emission to be controlled and modified into stimulated emission (Saiyan Emanation).

Possible crystals: There are many crystals that may have gain potentials that embody the characteristics listed above. Some of these crystals may include Ti³⁺:Al₂O₃, Nd: YAG, Cs: YAG, or any other crystal/chemical compound that has an intrinsic gain potential.

The gain medium may be cut, fabricated, polished, and coated before it is able to effectively provide a gain potential.

The gain medium may be spherical, rectangular, triangular, or any other type of crystalline configuration that allows for the harnessing and amplification of photonic energy.

The gain medium may also be cut at a specific incident angle that may allow for the seamless transmission of light with minimal reflection losses. This angle may be a Brewster Angle, or any other type of configuration that decreases reflection and allows for seamless transmission of light into the gain medium.

### Photoelectric Material

This is the site where the photoelectric effect takes place within the solid-state device. The material that is used here may be highly excitable by photonic energy. The material may also be specifically excited by specific wavelengths of light. For instance, this material may be selectively excited by the peak emission bandgap of the gain medium associated with this solid-state device. This allows for the newly created photonic energy from the gain medium to excite the electrons within the photoelectric material generating a useable electric current.

Chemical composition: This material may be composed of a variety of different chemical or molecular compositions. Of which, specific chemical or molecular compounds such as GaAs, InGaN, GaInP, polycrystalline silicon, SiN, CdTe, or any other chemical compound that may partake in the photoelectric effect. Another important characteristic of the material may be for its peak absorption bandgap to match the associated gain medium's peak emission bandgap.

Assembly: This material may be coated with an antireflective coating, dichromatic coating, or any other coating that decreases the amount of photonic energy that is lost due to reflection. This prevents the loss of photonic energy that is necessary to stimulate the movement of electrons within the material. By having this coating, the necessary light is directed and evenly distributed across the faces of the photoelectric material. This increases the instances of freely moving electrons allowing the conversion of photonic to electrical energy to become increasingly more efficient. There may also be a highly reflective mirror that lies on the back of the solid-state device. This allows for light not initially absorbed by the gain medium to be directed back into the crystal to initiate continued stimulated emission.

Coatings may be deposited using electron beam physical vapor deposition, ion assisted deposition, ion beam sputtering, or any other type of coating deposition process that allows for the effective distribution of coatings onto the faces of the photoelectric material.

The coatings may be evaporated evenly over the faces of the photoelectric material. This allows for the coating to evenly act on the entire face of the material increasing the amount of available surface area for the photovoltaic effect to continuously occur. The photoelectric material is then effectively adhered to the back of the gain medium. This may be done using a resin whose index of refraction matches the gain medium allowing for light to seamlessly pass through onto the face of the photoelectric material.

As light enters the gain medium, it may allow for stimulated emission (Saiyan Emanation) to occur within the gain medium. Newly generated energy may exit the medium in the form of its peak emission bandgap. This light may then become readily absorbed by the photoelectric material. Once the photonic energy undergoes the photoelectric effect within this material, electrical energy may be harnessed and implemented into a variety of use cases.

It should be understood that all of the embodiments and examples described herein are merely exemplary and should be considered as non-limiting.

What is claimed is:

1. A device for converting photonic energy to electrical energy, comprising:
one or more photonic collectors configured to collect photonic energy;
one or more mirrors configured to concentrate the collected photonic energy;
one or more gain mediums configured to receive, on one or more absorption faces, the concentrated photonic energy; and
a photoelectric material configured to receive the photonic energy from the one or more gain mediums and convert the photonic energy into electrical energy,
wherein the one or more gain mediums comprise a crystalline lattice structure selected from the group consisting of: Ti³⁺:Al₂O₃, Nd: YAG, Yb³⁺:YAG, and Ce:YAG.

2. The device of claim 1, wherein the one or more photonic collectors comprise a crystalline lattice structure selected from the group consisting of: Al₂O₃, Ti³⁺:Al₂O₃, Nd:YAG, Yb³⁺:YAG, and Ce:YAG.

3. The device of claim 1, wherein the one or more photonic collectors comprise a coating configured to transmit wavelengths of photonic energy within an absorption bandgap of the one or more photonic collectors.

4. The device of claim 3, wherein the coating further comprises an anti-reflective coating and a reflective coating.

5. The device of claim 4, wherein the reflective coating is configured to allow certain wavelengths of photonic energy to lace back and forth within the one or more photonic collators.

6. The device of claim 3, wherein the coating is located on a surface of the one or more photonic collectors where the photonic energy enters.

7. The device of claim 1, wherein the one or more mirrors comprise a coating configured to reflect wavelengths of photonic energy within an absorption bandgap of the one or more gain mediums.

8. The device of claim 1, wherein the one or more gain mediums comprise a coating configured to absorb and transmit wavelengths of photonic energy within an absorption bandgap of the one or more gain mediums.

9. The device of claim 8, wherein the coating further comprises an anti-reflective coating and a reflective coating.

10. The device of claim 9, wherein the reflective coating is configured to allow certain wavelengths of photonic energy to lace back and forth within the one or more gain mediums.

11. The device of claim 8, wherein the coating is located on a surface of the one or more gain mediums facing the concentrated photonic energy.

12. The device of claim 1, wherein the photoelectric material comprises an index-matching coating configured to match an emission spectrum of the one or more gain mediums.

13. A device for converting photonic energy to electrical energy, comprising:
one or more photonic collectors configured to collect photonic energy;
one or more mirrors configured to concentrate the collected photonic energy;
one or more gain mediums configured to receive, on one or more absorption faces, the concentrated photonic energy; and
a photoelectric material configured to receive the photonic energy from the one or more gain mediums and convert the photonic energy into electrical energy,
wherein at least one face of the one or more gain mediums is oriented at an incident angle that facilitates entry of photonic energy comprising wavelengths within an absorption bandgap of the one or more gain mediums.

14. The device of claim 13, wherein the at least one face of the one or more gain mediums is polarized.

15. The device of claim 13, wherein the one or more gain mediums are configured such that:
photonic energy enters the at least one face of the one or more gain mediums; and
photonic energy is emitted from at least one other face of the one or more gain mediums, wherein the emitted photonic energy comprising a different wavelength than the entering photonic energy.

16. The device of claim 15, wherein the photoelectric material has a first face and a second face,
wherein the first face is oriented towards an emission face of the one or more gain mediums that facilitates entry of photonic energy emitted from the one or more gain mediums, and wherein the second face is reflective to reduce photonic energy loss.
